(19) United States
(12) Patent Application Publication
(10) Pub. No.: US 2025/0087772 A1
(43) Pub. Date: Mar. 13, 2025

(54) Battery-Cell Testing Apparatuses Having Thermal-Runaway Safety Features

(71) Applicant: SES (Shanghai) Co. Ltd., Shanghai (CN)

(72) Inventors: Yong Duan, Shanghai (CN); LuYong Shen, Shanghai (CN); Biao Xu, Shanghai (CN)

(21) Appl. No.: 18/808,260

(22) Filed: Aug. 19, 2024

Related U.S. Application Data
(60) Provisional application No. 63/537,010, filed on Sep. 7, 2023.

(51) Int. Cl. H01M 10/42

(52) U.S. Cl. CPC H01M 10/4285

(57) ABSTRACT

A cell-testing apparatus for testing one or more cells includes a cell-test enclosure that includes at least one internal vent. The cell-testing apparatus also includes an external housing that contains the cell-test enclosure and that includes at least one exhaust vent that vents to outside the external housing. During testing, the cell-test enclosure is located within the external housing so as to define at least one explosion-gas pathway from the at least one internal vent to the at least one exhaust vent. In some embodiments, the venting axis of the internal vent(s) is perpendicular to the venting axis of the exhaust vent(s). In some embodiments, the vents each comprise one or more fenestrated plates. In some embodiments, the cell-test enclosure is a drawer-type enclosure including a cabinet and a drawer that is designed and configured to receive a battery cell for testing.

### CROSS-REFERENCE TO RELATED APPLICATIONS

This application claims the benefit of priority of U.S. Provisional Patent Application Ser. No. 63/537,010, filed Sep. 7, 2023, and titled “Battery-Cell Testing Apparatuses Having Thermal-Runaway Safety Features”, which is incorporated herein by reference in its entirety for all purposes.

### FIELD OF THE INVENTION

The present invention generally relates to the field of testing of battery cells. In particular, the present invention is directed to battery-cell testing apparatuses having thermal-runaway safety features.

### BACKGROUND

Battery cells, such as individual pouch cells and multiple cells contained in a battery module or battery pack, need to be tested during the design phase and during the manufacturing phase, such as for quality control purposes. During testing, battery cells can experience thermal runaway, such as combustion or explosion, for example, due to internal short circuiting. Combustion and explosion during testing is more common with certain cell chemistries than with others. For example, battery cells having plating-stripping type lithium-metal anodes are prone to dendrite formation during charging, and the resulting dendrites can penetrate the separator and contact the cathode during cycle testing, causing an electrical short. Depending on the type of electrolyte in the cell, the electrical shorting can cause the cell to catch fire and/or explode. Safety during testing is always a paramount consideration in the testing of battery cells that could potentially catch fire and/or explode, and improvements to testing apparatuses to increase their safety continue to be made.

### SUMMARY OF THE DISCLOSURE

In an implementation, the present disclosure is directed to a cell-testing apparatus for testing one or more cells, which includes a cell-test enclosure that includes an interior space configured for containing the one or more cells during the testing, the cell-test enclosure including an internal vent having a venting axis, wherein, during testing, the cell-test enclosure is sealed except for the internal vent that vents to a location outside the cell-test enclosure; and an external housing that contains the cell-test enclosure and includes at least one exhaust vent that each vent to outside the external housing along a corresponding exhausting axis, wherein, during testing, the external housing is sealed except for the at least one exhaust vent; wherein, during testing, the cell-test enclosure is located within the external housing: so as to define at least one explosion-gas pathway from the explosion vent to the at least one exhaust vent; and so that either: the venting axis of the internal vent is perpendicular to each exhausting axis of the at least one exhaust vent; or the venting axis of the internal vent is parallel to each exhausting axis of the at least one exhaust vent.

### BRIEF DESCRIPTION OF THE DRAWINGS

For the purpose of illustration, the accompanying drawings show aspects of one or more embodiments of the disclosure. However, it should be understood that the scope of this disclosure is not limited to the precise arrangements and instrumentalities shown in the drawings, wherein:

FIG. 1 is an isometric view of an example cell-testing apparatus made in accordance with aspects of the present disclosure that includes a vented cell-test enclosure located inside a vented external housing;

FIG. 2A is a simplified representational transverse cross-section of the example cell-testing apparatus of FIG. 1 made in accordance with aspects of the present disclosure showing the cell-test enclosure located within the external housing;

FIG. 2B is the same simplified representational transverse cross-section as FIG. 2A but with an explosion of the device-under-test having occurred within the cell-test enclosure;

FIG. 3 is a reduced exploded isometric view of the cell-test enclosure of the cell-testing apparatus of FIG. 1;

FIG. 4 is an enlarged isometric view of an example alternative drawer of a cell-test enclosure configured for holding a single pouch-type cell while the cell is clamped within a pressure-applying jig;

FIG. 5A is a reduced isometric view of the external housing of the cell-testing apparatus of FIG. 1, showing a door of the external housing in a closed-and-secured state and showing a first lateral side of the external housing having exhaust vents;

FIG. 5B is a different isometric view of the same external housing as FIG. 5A, but showing the door in an opened-and-unsecured state and showing a second lateral side of the external housing also having exhaust vents;

FIG. 6A is a reduced isometric partial view of a corner of the external housing of FIGS. 1, 5A, and 5B, showing one of the exhaust-vent panels partially engaged with a pair of vertically extending channels formed by corresponding respective L-shaped members secured to the external housing;

FIG. 6B is the same partial view of the external housing as in FIG. 6A but without that one of the exhaust-vent panels;

FIG. 7A is an isometric view of an example fenestrated plate that is made in accordance with aspects of the present disclosure and can be used to form a vent panel of the present disclosure;

FIG. 7B is an isometric view of another example fenestrated plate that is made in accordance with aspects of the present disclosure and can be used to form a vent panel of the present disclosure; and

FIG. 8 is a partial isometric view of the front end of the external housing of the cell-testing apparatus of FIG. 1, showing the door in a closed-and-secured state, with the four latches fully engaged.

### DETAILED DESCRIPTION

The entire contents of the appended claims are incorporated into this Detailed Description section as if originally presented herein.

In some aspects, the present disclosure is directed to battery-cell-testing apparatuses (or simply “cell-testing apparatuses” hereinafter) that each include safety features for minimizing the impact to the environment surrounding the cell-testing apparatus when the one or more battery cells being tested catch fire and/or explode. As alluded to in the Background section above, each cell-testing apparatus may be configured to test a single cell (e.g., a lithium-metal cell or other type of cell that may experience electrical shorting and/or other catastrophic-failure mechanism) or a group of cells, such as are present in a battery module or a battery pack, among other alternatives.

At a high level and in some embodiments, a cell-testing apparatus of the present disclosure includes a vented cell-test enclosure and a surrounding vented external housing, with the vented cell-test enclosure being located within the vented external housing and the various vents being located so as to provide one or more indirect pathways from the vent(s) of vented cell-test enclosure to vent(s) of the vented external housing so as to inhibit any flame emanating from inside the cell-test enclosure from exiting the external housing into the surrounding environment and to dissipate energy in the blast front of an explosion inside the cell-test enclosure. An example embodiment including these and other safety features is described below in detail and shown in the accompanying drawings.

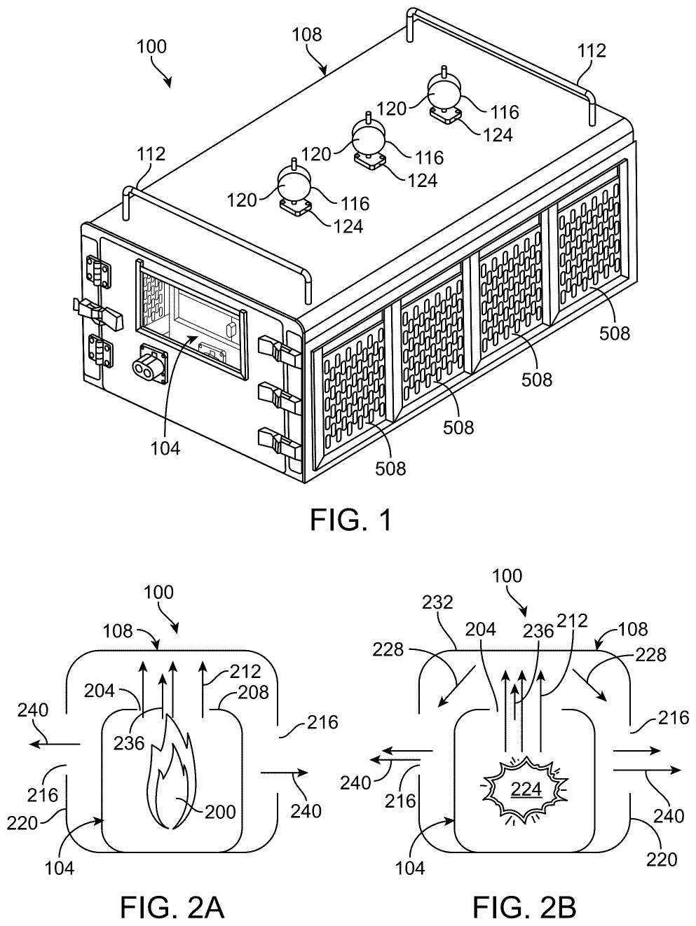

FIG. 1 shows an example cell-testing apparatus 100 that includes a vented cell-test enclosure 104 located inside a vented external housing 108. In the embodiment shown, the cell-testing apparatus 100 includes a pair of handles 112 that are configured for one or more human users (not shown) to grasp them and use them to lift and/or move the cell-testing apparatus. Each of the vented cell-test enclosure 104 and the vented external housing 108 are described below in detail. Before proceeding to those details, however, FIGS. 2A and 2B illustrate the relationship between the cell-test enclosure 104 and the external housing 108 that provide the above-mentioned indirect pathway(s) within the external housing.

FIG. 2A shows a transverse cross-section of the cell-testing apparatus 100 showing the cell-test enclosure 104 located within the external housing 108, with a flame 200 representing the combustion of a device-under-test (DUT), which, as mentioned above, can be a single cell or a group of cells (e.g., battery module, battery pack, etc.), among other things. Relative to the orientation of the cell-testing apparatus 100 in FIG. 2A, the cell-test enclosure 104 includes an internal vent 204 in/on an upper wall 208 of the cell-test enclosure, and the flame 200 and combustion products 212 are shown exiting the cell-test enclosure through the internal vent. As also seen in FIG. 2A, the external housing 108 includes a pair of exhaust vents 216 in/on sidewalls 220 of the external housing. As can be readily appreciated, any flame 200 exiting the internal vent 204 of the cell-test enclosure 104 would have to wind its way through the space between the cell-test enclosure and the external housing 108 before reaching the exhaust vents 216, which greatly lessens the likelihood of any flame reaching the exterior of the external housing.

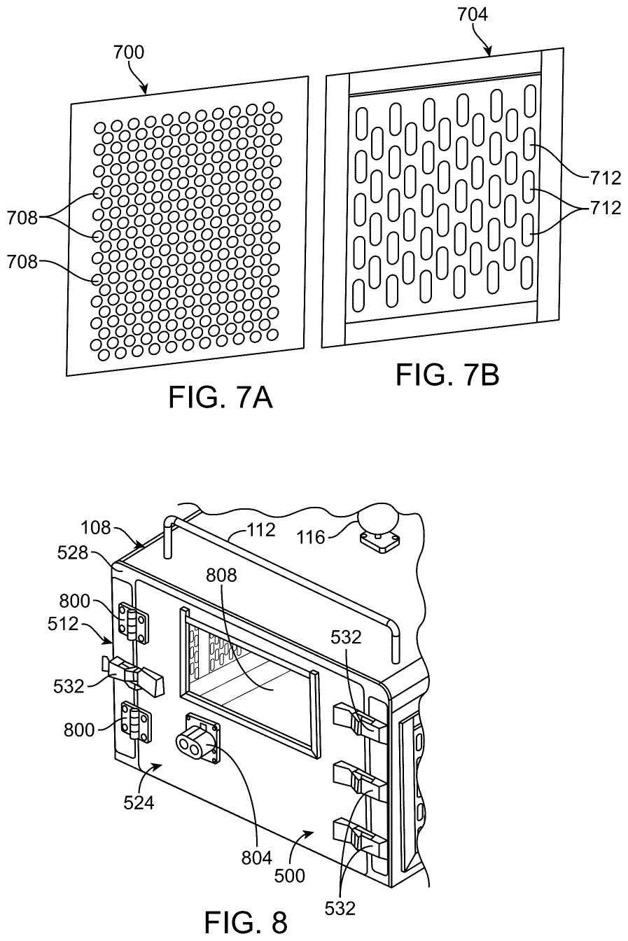

FIG. 2B shows the same transverse cross-section as FIG. 2A but with an explosion 224 of the DUT having occurred within the cell-test enclosure 104. As seen in FIG. 2B and as represented by the arrows, the explosion has caused a blast front (i.e., high-pressure gas) 228 to propagate through the space between the cell-test enclosure 104 and the external housing 108 before reaching the exhaust vents 216 and being vented to the outside of the external housing. As the blast front 228 propagates through that space, the locations of the internal vent 204 and the exhaust vents 216 relative to one another causes the gas flow to impact against the upper wall 232 of the external housing 108, deflect therefrom to both the left and the right, and then exit the external housing through the exhaust vents 216 on the sidewalls 220 of the external housing. As can be readily envisioned from FIG. 2B, the locations of the internal vent 204 and the exhaust vents 216, in conjunction with the positioning of the cell-test enclosure 104 within the external housing 108 and optionally with specially designed vents (sec, e.g., FIGS. 7A and 7B), combine with one another to dissipate energy from the blast front 228 so that by the time the gas from the explosion 224 exits the exhaust vents in the external housing to the surrounding environment, it has so little energy (e.g., velocity) that it is unlikely to damage whatever apparatus(es) (e.g., other cell-testing apparatus(es), instrumentation, structure(s), etc.) that may be located in close proximity to the cell-testing apparatus 100.

In the example of FIGS. 2A and 2B, it is seen that the venting axis 236 of the internal vent 204 of the cell-test enclosure 104 is perpendicular to both of the exhausting axes 240 of the exhaust vents 216 in the external housing 108. As used herein and in the appended claims, the “venting axis” and the “exhausting axis” of, respectively, an internal vent 204 and an exhaust vent 216, is an axis that is perpendicular to a vent opening or to the plane of a vent panel, depending on the situation. This relationship between the relevant venting and exhausting axes forces the explosion gas to change direction within the external housing and thereby contribute to diminishing the amount of energy in the explosion gas. It is noted that orientation of the cell-testing apparatus 100 need not be as shown in FIGS. 2A and 2B, wherein it is implied that a direction into and out of the page containing these figures is horizontal. For example, that direction may be vertical or at any oblique angle. In addition, those skilled in the art will readily appreciate that each of the transverse cross-sections in FIGS. 2A and 2B may be rotated from the orientation shown to any angle between 0° and 360°.

Although each of the internal vent 204 and exhaust vents 216 is depicted as a relatively large opening in the respective structure, as alluded to above and as exemplified below each of these vents will typically be composed of a plurality of smaller openings that further inhibit a combustion flame 200 from reaching the environment surrounding the cell-testing apparatus 100 and/or further dissipate energy in a blast front 228. It is also noted that the number of vents provided can differ from the vents illustrated, as can the locations of the vents. For example, and using the general configurations of the cell-test enclosure 104 and external housing 108 shown in the accompanying figures, the internal vent 204 of the cell-test enclosure 104 may remain where it is, while the external housing 108 may include a single exhaust vent in its rear wall (not shown). In this example, the venting and exhausting axes are perpendicular to one another. As another example, the cell-test enclosure 104 may have an internal vent on its rear wall (not shown), and the external housing may include one or more exhaust vents on any one or more of its sidewalls, top wall, and bottom wall (not shown). Here, too, the venting axis of the internal vent would be perpendicular to the venting axis of each exhaust vent provided. In such embodiments, each of the exhaust vents 216 provided to the external housing 108 may be located only toward the opposite end of the external housing relative to where the internal vent 204 of the cell-test enclosure 104 is located. This would maximize the distance that a flame 200 or blast front 228 would have to travel internally within the external housing 108 from the internal vent 204 to the exhaust vent(s) 216. In yet another example, the cell-test enclosure 104 may include an internal vent on each of its lateral sides (not shown), and the external housing 108 may include at least one exhaust vent on one or both of the top wall and the bottom wall (not shown). In this case, the venting and exhausting axes of the internal vents are perpendicular to the venting axis of each exhaust vent provided on the external housing 108.

Each of the foregoing examples has the venting axis of each internal vent perpendicular to the exhausting axis of each exhaust vent. However, in some embodiments, this need not be so. Rather, in some embodiments the venting and exhausting axes of, respectively, the internal vent(s) and the exhaust vent(s) may be parallel with one another (not shown). In such cases, each internal vent is laterally offset from each proximate exhaust vent located on the same side (e.g., lefthand side, righthand side, upper side, lower side) of the respective cell-test enclosure and external housing so that there cannot be direct linear flow from any internal vent to any exhaust vent. For example, the cell-test enclosure 104 may have an internal vent located on each lateral side proximate to its front end (not shown), while the external housing 108 may have an exhaust vent located on each lateral side but proximate to its back end (not shown). In this configuration, any blast front exiting the internal vents would first impact the sidewalls of the external housing 108, deflect toward the opposite end of the external housing, and then change direction again to exit the external housing through the exhaust vents. Many other arrangements of internal and exhaust vents are possible.

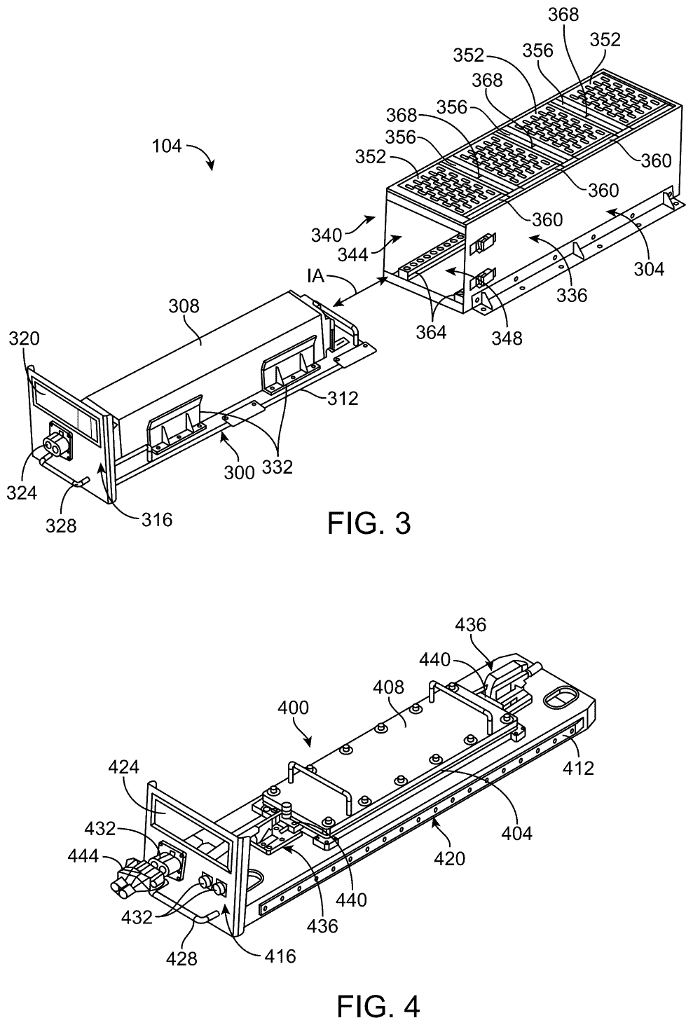

FIG. 3 is an exploded view of the cell-test enclosure 104 of the cell-testing apparatus 100 of FIG. 1. In this example, the cell-test enclosure 104 is a drawer-type enclosure having a drawer 300 that slidably engages a corresponding cabinet 304. In the example shown, the drawer 300 is configured for holding a battery module 308 during testing. The drawer 300 includes a base 312 and a closure 316 that, when the drawer is fully engaged with the cabinet 304, seals the cell-test enclosure 104. In this example, the closure 316 includes a transparent window 320 made of a suitable explosion-proof material, such as explosion-proof glass or quartz, among others, to allow a user (not shown) to see inside the cell-test enclosure 104 when the drawer 300 is closed. The window 320 may be engaged with the closure 316 in any suitable manner, such as being slid into channels and/or mechanically fastened to the closure. The closure 316 in the example also includes electrical connections 324 for electrically connecting the battery module to a cycler (not shown) and/or other piece of testing equipment, as well as a handle 328 that a user can easily grab to open and close the drawer 300. When the drawer 300 is in the cabinet 304 and is closed, a set of latches 332 (here four spring-type latches, with two on each side) firmly secures the drawer in the cabinet. In this example, the spring-type latches 332 provide a measure of energy dissipation so as to reduce the likelihood of the drawer 300 being blown out of the cabinet 304 by a violent explosion inside the cell-test enclosure 104.

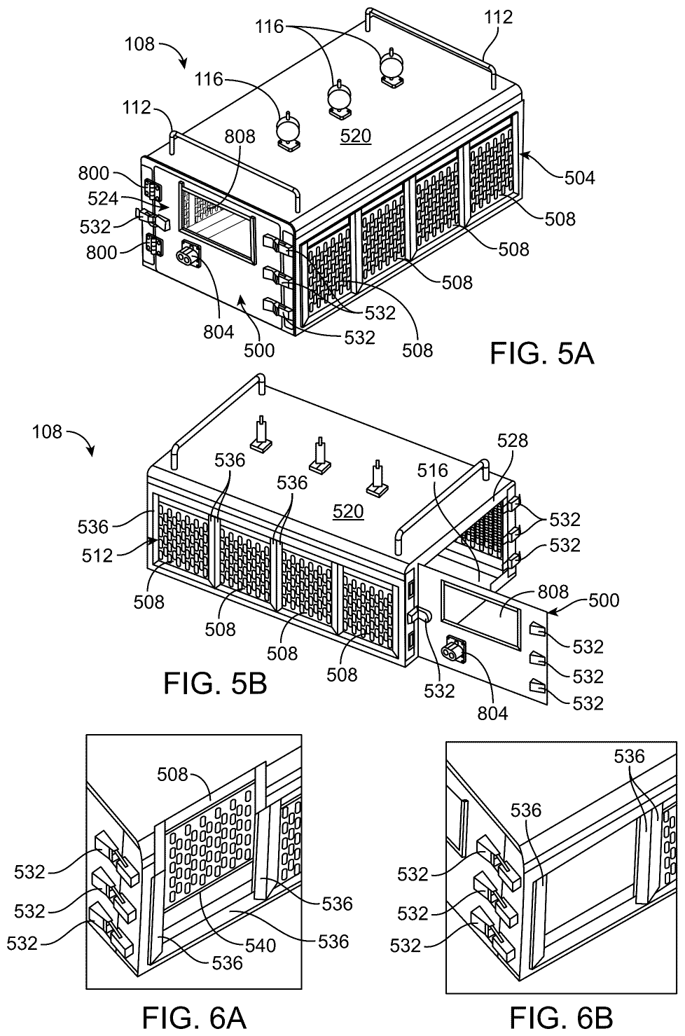

In this example, the cabinet 304 includes a pair of sidewalls 336 extending between a pair of ends 340, with one end having an opening 344 for receiving the drawer 300 and the other end (not seen) having an end wall. The cabinet 304 may have a bottom wall 348. Alternatively, a bottom wall of the external housing 108 (FIGS. 5A, 5B, and 8) may double as the bottom wall of the cell-test enclosure 104 when the cabinet 304 is secured to the bottom wall of the external housing using a pair of brackets at the lower edges of the sidewalls of the cell-test enclosure (not shown). In the example shown, the upper side of the cabinet 304 has four internal-vent panels 352, each of which may, but need not necessarily, be a double-layer vent panel as seen in FIGS. 7A and 7B. In an example, the upper ends of the sidewalls may be tied together with tie members 356 that may be located at the locations where vent openings in the four internal-vent panels 352 are not present. In FIG. 3, such tie members 356 may be present at the three such locations shown there.

In some embodiments, each internal-vent panel 352 is slidably engaged with transversely extending channels that may correspond to and/or provide the tie members (not shown). In other embodiments, the four internal-vent panels 352 may be slidably engaged with longitudinally extending sidewall channels, here formed by L-shaped hold-downs 360 located near the upper ends of the sidewalls 336 and the (rear) end wall (not seen). In such an embodiment, the four internal-vent panels 352 would be installed in a sequence, with the right-most internal-vent panel being installed first from the drawer end of the cabinet 304 and slid all the way to the right, and the left-most internal-vent panel being installed last. When the drawer 300 is closed in such an embodiment, the upper end of the closure 316 may be configured to extend upwardly so as to retain the four internal-vent panels 352 in the sidewall channels. In the embodiment shown, but for the tie members 356 and/or hold-downs 360, the entire upper side of the cabinet 304 includes internal vents. In other embodiments, the cabinet 304 may include a lesser expanse of internal vents, such as about 30%, about 40%, about 50%, about 60%, or about 75% of the total area of the upper side of the cabinet, with the remainder being closed by a solid wall and/or one or more tie members 356 and/or other structure.

In some embodiments, the drawer 300 slidably engages rails 364 in the corresponding cabinet 304. The drawer 300 may be inserted into cabinet 304 along an insertion axis IA.

FIG. 4 shows an alternative drawer 400 configured for holding a single pouch-type cell 404 while the cell is clamped within a pressure-applying jig 408. The drawer 400 of FIG. 4 is generally similar to the drawer 300 of FIG. 3 in terms of its cabinet-engaging feature and configuration. The drawer 400 has rails 412 that may slidingly engage a cabinet (not shown). Also like the drawer 300 of FIG. 3, the drawer 400 of FIG. 4 includes a closure 416 and a base 420. The closure 416 of the drawer 400 also includes an explosion-proof window 424, a handle 428, and electrical connections 432 appropriate to the testing of the cell 404 being tested. In this example, the base 420 of the drawer 400 of FIG. 4 includes electrical contacts 436 for electrically contacting tabs 440 of the cell 404. FIG. 4 also shows an electrical connector 444 that provides the requisite electrical connections between the electrical connections 432 on the closure 416 of the drawer 400 and the electrical connections on the door of the external housing 108 (see FIG. 8). As can be appreciated, when the drawer 400 is fully closed, the electrical connections 432 on the closure 416 align with the electrical connections on the door of the external housing 108 (see FIG. 8) so that the act of closing the door completes the connection between the electrical connections on the door and the electrical connections on the closure via the electrical connector 444.

FIGS. 5A and 5B are differing views of the external housing 108, with FIG. 5A showing a door 500 of the external housing 108 in a closed-and-secured state and a first lateral side 504 of the external housing having exhaust vents 508 and FIG. 5B showing the door 500 in an open-and-unsecured state and a second lateral side 512 of the external housing also having exhaust vents 508. In this example, the external housing 108 includes a solid bottom wall 516, a solid rear end wall (not seen), and a solid top wall 520. The front end 524 of the external housing 108 includes a structural door frame 528 that supports the door 500 and latch mechanisms 532 and provides rigidity to the external housing. Each of the lateral sides 504, 512 of the external housing 108 includes vertical supports 536 that tic-together the top and bottom walls 520, 516 and provides rigidity to the external housing. In this example, these vertical supports 536 are located between immediately adjacent ones of the four exhaust-vent panels 508 on each of the lateral sides 504, 512 of the external housing 108. In some embodiments, each of the exhaust-vent panels 508 may be the double-layer vent panel depicted in FIGS. 7A and 7B.

In some embodiments, each exhaust-vent panel 508 may be slidably engaged with vertically extending channels that may correspond to and/or provide the vertical supports 536. In the embodiment shown, the vertical supports 536 are L-shaped members. In particular, FIG. 6A shows an exhaust-vent panel 508 partially engaged with a pair of vertically extending channels formed by corresponding respective L-shaped members 536 secured to the external housing 108. A third L-shaped member 536 is located at the bottom of the opening that receives the exhaust-vent panel 508 to capture a lower edge 540 of the exhaust-vent panel. FIG. 6B shows the opening in the lateral side 504 of the external housing 108 without the exhaust-vent panel 508 installed.

In other embodiments, the four exhaust-vent panels on each lateral side of the external housing may be slidably engaged with longitudinally extending channels formed by L-shaped hold-downs located near the upper and lower ends of the corresponding sidewall and the front end of the external housing proximate to the door frame. In such an embodiment, the four exhaust-vent panels must be installed in a sequence, for example, and relative to FIG. 5B, with the right-most vent panel being installed first from the rear end of the external housing and slid all the way to the right, and the left-most vent panel being installed last. In the embodiment shown, but for the vertical supports 536, each entire lateral side 504, 512 of the external housing 108 includes exhaust-vent panels. In other embodiments, each lateral side 504, 512 may include a lesser expanse of exhaust vents, such as about 30%, about 40%, about 50%, about 60%, or about 75% of the total area of that lateral side, with the remainder being closed by a solid wall and/or one or more vertical supports and/or other structure. In some embodiments, the percentages of the exhaust vents on the two lateral sides may be equal to one another or different from one another.

FIGS. 7A and 7B show, respectively, first and second fenestrated plates 700, 704 that, when overlaid with one another, provide a vent panel of the present disclosure, such as any of the internal-vent panels 352 and exhaust-vent panels 508. The first fenestrated plate 700 has openings 708 (only three labeled to avoid clutter) and the second fenestrated plate 704 has openings 712 (only three labeled to avoid clutter). In this example, the first fenestrated plate 700 of FIG. 7A has more, but smaller, openings than the second fenestrated plate 704 of FIG. 7B. In some embodiments, the first and second fenestrated plates 700, 704 may be fastened to one another to provide a unitary vent panel, while in some embodiments the first and second fenestrated plates may remain separate from one another even when deployed in a cell-testing apparatus of the present disclosure, such as the cell-testing apparatus 100 of the present drawings. When fastened together, the first and second fenestrated plates 700, 704 may be secured to one another using any one or more fastening means, such as, but not limited to, mechanical fastening, welding, adhesive bonding, fusion bonding, brazing, mechanical interlocking, etc. In some embodiments, the first fenestrated plate 700 with the larger number of smaller openings 708 may be located so as to face the interior of the component with which it is engaged (i.e., either the cell-test enclosure 104 or the external housing 108), with the second fenestrated plate 704 with the smaller number of larger openings 712 being located downstream of the first fenestrated plate 700 relative to the flow direction of the explosion gas.

In some embodiments, the two layers of the first and second fenestrated plates 700, 704 buffer and/or absorb any flame 200 and/or impact force. The openings 708 (e.g., holes and/or slots) in the first fenestrated plate 700 and the openings 712 in the second fenestrated plate 704 may be staggered relative to one another so that when a flame 200 and/or pressure wave pass through the first plate, the second plate can absorb the remaining flame and/or pressure wave that has passed through the first plate. If the dimension(s) of the openings 708, 712 is/are too large, the absorption ability may be too small. On the other hand, if the dimension(s) of the openings 708, 712 is/are too small, the pressure may not be released quickly enough, and this could cause other damage. In some embodiments, a single fenestrated plate may be used. In some embodiments, three or more fenestrated plates overlaid with one another can be used. It is noted that the first and second fenestrated plates 700, 704 may also or alternatively be referred to as “pressure-release plates” due to their function and that, similarly, a vent panel may be referred to as a “pressure-release panel”.

FIG. 8 shows the door 500 on the front end 524 of the external housing 108 in a closed-and-secured state, with the four latches 532 fully engaged. In this example, the door 500 is hingedly connected to the door frame 528 on one of its lateral sides 512 via a pair of hinges 800. One of the four latches 532 is located between the pair of hinges 800. In this example, this latch 532 is provided to supplement the hinges 800 relative to the ability to resist a blast impulse force caused by an explosion within the cell-test enclosure 104 (not shown in FIG. 8). The latches 532 are of a spring-type, which provides a measure of energy dissipation so as to reduce the likelihood of the door 500 being blown off of the external housing 108 in the event of a violent explosion inside the cell-test enclosure 104. In this example, the door 500 also includes external electrical connections 804 for connecting the cell-testing apparatus 100 to a cycler and/or other piece of testing equipment (not shown). FIG. 8 also shows the door 500 as including a transparent window 808 made of a suitable explosion-proof material, such as explosion-proof glass or quartz, among others, to allow a user to see inside the external housing 108 when the door 500 is closed. The window 808 may be engaged with the door 500 in any suitable manner, such as being slid into channels and/or mechanically fastened to the door.

Referring back to FIG. 1 and also FIGS. 3, 5A, and 5B, in the example shown, the cell-testing apparatus 100 includes a plurality of, here, three, displacement gauges 116 to measure height change of an internal measured object. Each of the displacement gauges 116 in this embodiment includes a head 120 located outside of the external housing 108 and a shaft 124 that extends from the head 120 into the interior of the cell-test enclosure 104 so as to contact the test specimen or pressure-applying jig 408 when the cell-test enclosure is present within the external housing and the test specimen/pressure-applying jig is present within the cell-test enclosure. The shaft 124 of each displacement gauge 116 extends through a corresponding first aperture (not shown) in the external housing and a second aperture 368 (see FIG. 3) in the three tie members 356 on the upper wall of the cell-test enclosure 104. In this example, the displacement gauges 116 are installed after the cell-test enclosure 104 has been properly installed into the external housing 108 so that the second apertures 368 of the cell-test enclosure properly align with the first apertures of the external housing. The function of the displacement gauges 116 is to monitor the expansion of the test specimen (e.g., the swell dimension). When the test specimen is a lithium-metal cell or battery pack being charged or discharged, the thickness of the cell or battery pack changes. The displacement gauges 116 measure and monitor the swell dimension. In some embodiments, the displacement gauges 116 or other displacement sensors could be connected to a computer (not shown), with the results being displayed on a computer screen. In some embodiments, the external-type displacement gauges 116 shown may be replaced by displacement sensors that are located entirely internally to the cell-test enclosure.

Various modifications and additions can be made without departing from the spirit and scope of this disclosure. Features of each of the various embodiments described above may be combined with features of other described embodiments as appropriate in order to provide a multiplicity of feature combinations in associated new embodiments. Furthermore, while the foregoing describes a number of separate embodiments, what has been described herein is merely illustrative of the application of the principles of the present invention. Additionally, although particular methods herein may be illustrated and/or described as being performed in a specific order, the ordering is highly variable within ordinary skill to achieve aspects of the present disclosure. Accordingly, this description is meant to be taken only by way of example, and not to otherwise limit the scope of this invention.

Exemplary embodiments have been disclosed above and illustrated in the accompanying drawings. It will be understood by those skilled in the art that various changes, omissions and additions may be made to that which is specifically disclosed herein without departing from the spirit and scope of the present invention.

What is claimed is:

1. A cell-testing apparatus for testing one or more cells, comprising:
a cell-test enclosure that includes an interior space configured for containing the one or more cells during the testing, the cell-test enclosure including an internal vent having a venting axis, wherein, during testing, the cell-test enclosure is sealed except for the internal vent that vents to a location outside the cell-test enclosure; and
an external housing that contains the cell-test enclosure and includes at least one exhaust vent that each vent to outside the external housing along a corresponding exhausting axis, wherein, during testing, the external housing is sealed except for the at least one exhaust vent;
wherein, during testing, the cell-test enclosure is located within the external housing:
so as to define at least one explosion-gas pathway from the explosion vent to the at least one exhaust vent; and
so that either:
the venting axis of the internal vent is perpendicular to each exhausting axis of the at least one exhaust vent; or
the venting axis of the internal vent is parallel to each exhausting axis of the at least one exhaust vent.

2. The cell-testing apparatus of claim 1, wherein the venting axis of the internal vent is perpendicular to each exhausting axis of the at least one exhaust vent.

3. The cell-testing apparatus of claim 1, wherein:
the cell-test enclosure has first and second ends spaced from one another, the internal vent being located between the first and second ends;
the external housing has third and fourth ends spaced from one another and has first and second sides extending between the third and fourth ends and being spaced from one another; and
the at least one exhaust vent including first and second exhaust vents located, respectively, on the first and second sides.

4. The cell-testing apparatus of claim 1, wherein the internal vent comprises a first fenestrated plate having a first configuration of openings.

5. The cell-testing apparatus of claim 4, wherein the internal vent comprises a second fenestrated plate that overlays the first fenestrated plate, the second fenestrated plate having a second configuration of openings that is different from the first configuration of openings.

6. The cell-testing apparatus of claim 5, wherein the first and second fenestrated plates are secured to one another to provide a first multi-layer pressure-release panel.

7. The cell-testing apparatus of claim 1, wherein the at least one exhaust vent comprises a third fenestrated plate having a third configuration of openings.

8. The cell-testing apparatus of claim 7, wherein the at least one exhaust vent comprises a fourth fenestrated plate that overlays the third fenestrated plate, the fourth fenestrated plate having a fourth configuration of openings that is different from the third configuration of openings.

9. The cell-testing apparatus of claim 8, wherein the third and fourth fenestrated plates are secured to one another to provide a second multi-layer pressure-release panel.

10. The cell-testing apparatus of claim 1, wherein the cell-test enclosure is a drawer-type enclosure.

11. The cell-testing apparatus of claim 10, wherein the cell-test enclosure includes a cabinet and a drawer movably engaged with the cabinet.

12. The cell-testing apparatus of claim 11, wherein the drawer is designed and configured to receive a battery module for testing.

13. The cell-testing apparatus of claim 11, wherein the drawer is designed and configured to receive a single battery cell for testing.

14. The cell-testing apparatus of claim 13, wherein the drawer is designed and configured to receive the single battery cell when the single battery cell is located within a pressure-applying jig.

15. The cell-testing apparatus of claim 11, wherein the drawer is secured in a closed state via a plurality of spring-type latches.

16. The cell-testing apparatus of claim 11, wherein the drawer includes a closure that comprises a first explosion-proof window.

17. The cell-testing apparatus of claim 16, wherein the external housing includes a second explosion-proof window that is in registration with the first explosion-proof window when the cell-test enclosure is operatively located within the external housing.

18. The cell-testing apparatus of claim 1, wherein the cell-test enclosure includes external first electrical connections for connecting the one or more cells to testing equipment.

19. The cell-testing apparatus of claim 18, wherein the external housing comprises a door having internal and external second electrical connections for making electrical connections with the testing equipment, wherein, when the door is closed, the internal second electrical connections are in registration with the external first electrical connections of the cell-test enclosure.

20. The cell-testing apparatus of claim 19, wherein an electrical connector electrically connects the internal second electrical connections to the external first electrical connections of the cell-test enclosure.
